(19) United States
(12) Patent Application Publication
(10) Pub. No.: US 2026/0082842 A1
(43) Pub. Date: Mar. 19, 2026

(54) SUBSTRATE PROCESSING METHOD

(71) Applicant: SEMES CO., LTD., Cheonan-si (KR)

(72) Inventors: Yong Jun KIM, Suwon-si (KR); Tae Keun KIM, Siheung-si (KR); Kyeong Min LEE, Hwaseong-si (KR); Jong Wan KWON, Seongnam-si (KR); Cheng Yeh HSU, Busan (KR)

(73) Assignee: SEMES CO., LTD., Cheonan-si (KR)

(21) Appl. No.: 19/333,616

(22) Filed: Sep. 19, 2025

(30) Foreign Application Priority Data
Sep. 19, 2024 (KR) 10-2024-0126545

(51) Int. Cl. H01L 21/02; H01L 21/18

(52) U.S. Cl. CPC H10P 70/10; H10P 10/12; H10P 90/123; H10P 90/128

(57) ABSTRACT

Provided is a substrate processing method, the method including: a substrate polishing operation of polishing a substrate; after the polishing operation, a treatment solution supplying operation of supplying a treatment solution containing a polymer and a volatile solvent onto the rotating substrate; after the treatment solution supplying operation, a liquid film forming operation of volatilizing the volatile solvent in the treatment solution to form a liquid film; and after the liquid film forming operation, an edge removing operation of removing the liquid film formed on an edge portion of the substrate and the edge portion of the substrate.

### CROSS-REFERENCE TO RELATED APPLICATION

This application claims priority to and the benefit of Korean Patent Application No. 10-2024-0126545 filed in the Korean Intellectual Property Office on Sep. 19, 2024, the entire contents of which are incorporated herein by reference.

### TECHNICAL FIELD

The present invention relates to a substrate processing method, and more particularly, to a substrate processing method of cleaning a substrate.

### BACKGROUND ART

In general, various processes, such as photo process, etching process, ion implantation process, and deposition process, are performed to manufacture semiconductor devices. Further, before and after the processes are performed, a cleaning process for cleaning particles remaining on a substrate is performed.

The hybrid bonding process is performed by bonding the pattern surfaces of substrates containing copper to each other, and in general, the substrate is polished, the polished substrate is cleaned, and then an edge trimming process is performed to remove an edge portion of the substrate to prevent damage to the substrate, and the bonding process is performed by re-cleaning the substrate to remove particles generated by the edge trimming process and bonding the two substrates. Polishing processes and devices are widely known as disclosed in Patent Document 1, and matters on edge trimming processes and devices are widely known as disclosed in Patent Document 2.

However, according to prior art, contaminants, such as particles scattered during the edge trimming process are likely to cause scratches on the substrate, and there is a problem that the process time increases as it needs to be cleaned multiple times, such as cleaning after the polishing process and cleaning after the edge trimming process.

(Patent Document 1) KR 10-2024-0079582 A

(Patent Document 2) KR 10-2020-0030450 A

### SUMMARY OF THE INVENTION

The present invention has been made in an effort to provide a substrate processing method of efficiently cleaning a substrate.

The present invention has also been made in an effort to provide a substrate processing method capable of preventing particles generated during a process of treating a substrate from contaminating the substrate.

The present invention has been made in an effort to provide a substrate processing method of efficiently bonding substrates.

Effects of the present disclosure are not limited to those described above and effects not stated above will be clearly understood to those skilled in the art from the specification and the accompanying drawings.

An exemplary embodiment of the present disclosure, a method of processinga substrate, the method may comprising, a substrate polishing operation of polishing a substrate; after the polishing operation, a treatment solution supplying operation of supplying a treatment solution containing a polymer and a volatile solvent onto the rotating substrate; after the treatment solution supplying operation, a liquid film forming operation of volatilizing the volatile solvent in the treatment solution to form a liquid film; and after the liquid film forming operation, an edge removing operation of removing the liquid film formed on an edge portion of the substrate and the edge portion of the substrate.

According to the exemplary embodiment of the present invention, wherein the edge removing operation may includes: a bead removing operation of removing the liquid film formed on an edge region of the substrate; and an edge trimming operation of removing the edge region of the substrate.

According to the exemplary embodiment of the present invention, wherein the bead removing operation and the edge trimming operation may be performed by mechanical cutting.

According to the exemplary embodiment of the present invention, wherein in the bead removing operation, a dissolution solution is supplied to the substrate to remove the liquid film formed on the edge portion, and in the edge trimming operation, the edge portion of the substrate may be removed by mechanical cutting.

According to the exemplary embodiment of the present invention, wherein in the liquid film forming operation, the supply of the treatment solution may be stopped.

According to the exemplary embodiment of the present invention, the method may further include after the edge removing operation, a liquid film removing operation of removing the liquid film from an entire region of the substrate.

According to the exemplary embodiment of the present invention, wherein in the liquid film removing operation, a removal solution may be supplied to the substrate to strip the liquid film from the substrate and at the same time dissolve and remove the liquid film.

According to the exemplary embodiment of the present invention, wherein the removal solution contains isopropyl alcohol (IPA).

According to the exemplary embodiment of the present invention, wherein in the liquid film removing operation, a stripping solution may be supplied to the substrate to strip the liquid film from the substrate.

According to the exemplary embodiment of the present invention, wherein in the liquid film removing operation, a dissolution solution may be supplied to the substrate to dissolve and remove the liquid film.

According to the exemplary embodiment of the present invention, wherein the mechanical cutting is performed by a cutting blade, and the method further may comprises, after the edge removing operation, a blade cleaning operation of cleaning the cutting blade.

According to the exemplary embodiment of the present invention, wherein the polymer may contains a resin.

According to the exemplary embodiment of the present invention, the method may further include a substrate bonding process of bonding a pattern surface of a second substrate where the liquid film removing operation has been performed to a pattern surface of a first substrate where the liquid film removing operation has been performed.

According to the exemplary embodiment of the present invention, wherein in the substrate polishing operation, a copper (Cu) film remaining on the substrate may be polished.

An exemplary embodiment of the present disclosure, a substrate processing method comprising: a substrate polishing operation of polishing a substrate; after the polishing operation, a treatment solution supplying operation of supplying a treatment solution containing a polymer and a volatile solvent onto the rotating substrate; after the treatment solution supplying operation, a liquid film forming operation of volatilizing the volatile solvent in the treatment solution to form a liquid film; after the liquid film forming operation, an edge removing operation of removing the liquid film formed on an edge portion of the substrate and the edge portion of the substrate; and after the edge removing operation, a liquid film removing operation of supplying a removal solution to the substrate to strip the liquid film from the substrate and at the same time dissolve and remove the liquid film.

According to the exemplary embodiment of the present invention, wherein the polymer contains a resin, and the removal solution may contains isopropyl alcohol (IPA).

According to the exemplary embodiment of the present invention, wherein the edge removing operation may includes: a bead removing operation of removing the liquid film formed on the edge portion of the substrate; and an edge trimming operation of removing the edge portion of the substrate.

According to the exemplary embodiment of the present invention, wherein in the bead removing operation, a dissolution solution is supplied to the substrate to remove the liquid film formed on the edge portion, and in the edge trimming operation, the edge portion of the substrate may be removed by mechanical cutting.

According to the exemplary embodiment of the present invention, wherein the dissolution solution may be isopropyl alcohol (IPA).

An exemplary embodiment of the present disclosure, a substrate processing method comprising: a substrate polishing operation of polishing a substrate with a polishing pad; after the polishing operation, a treatment solution supplying operation of supplying a treatment solution containing a polymer and a volatile solvent onto the rotating substrate; after the treatment solution supplying operation, a liquid film forming operation of forming a liquid film of the treatment solution by stopping the supply of the treatment solution, and volatilizing the volatile solvent in the treatment solution and solidifying or curing the treatment solution; after the liquid film forming operation, an edge removing operation of removing the liquid film formed on an edge portion of the substrate and the edge portion of the substrate; and after the edge removing operation, a liquid film removing operation of supplying a removal solution to the substrate to strip the liquid film from the substrate and at the same time dissolve and remove the liquid film, wherein the edge removing operation includes: a bead removing operation of removing the liquid film formed on an edge region of the substrate; and an edge trimming operation of removing the edge region of the substrate, in the bead removing operation, a dissolution solution is supplied to the substrate to remove the liquid film formed on the edge region, and in the edge trimming operation, the edge region of the substrate may be removed by mechanical cutting.

According to the exemplary embodiment of the present invention, it is possible to improve substrate treating efficiency.

Further, according to the exemplary embodiment of the present invention, it is possible to prevent particles generated during a process of treating a substrate from contaminating the substrate.

According to the exemplary embodiment of the present invention, it is possible to efficiently bond substrates.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a substrate processing apparatus according to an exemplary embodiment of the present invention.

FIG. 2 is a diagram schematically illustrating a polishing chamber of FIG. 1.

FIG. 3 is a diagram schematically illustrating an exemplary embodiment of a liquid treating chamber of FIG. 1.

FIG. 4 is a flowchart of a substrate processing method of the present invention.

FIGS. 5 to 10 are diagrams schematically illustrating a process of treating a substrate using the substrate processing method of FIG. 4.

FIG. 11 is a diagram schematically illustrating an operation state of the substrate processing apparatus when a treatment solution supplying operation of FIG. 4 is performed, and FIG. 12 is an enlarged view of region A of FIG. 11 to illustrate a state of the substrate.

FIG. 13 is a diagram schematically illustrating an operation state of the substrate processing apparatus when a liquid film forming operation of FIG. 4 is performed, and FIG. 14 is an enlarged view of region A of FIG. 13 to illustrate a state of the substrate.

FIG. 15 is a diagram schematically illustrating an operation state of the substrate processing apparatus when a bead removing operation of FIG. 4 is performed, and FIG. 16 is an enlarged view of region A of FIG. 15 to illustrate a state of the substrate.

FIG. 17 is a diagram illustrating an operation state of the substrate processing apparatus after the bead removing operation of FIG. 4 is performed.

FIG. 18 is a diagram schematically illustrating a state of the substrate when an edge trimming operation of FIG. 4 is performed, and FIG. 19 is a diagram schematically illustrating a state of the substrate after the edge trimming operation of FIG. 4 is performed.

FIG. 20 is a diagram schematically illustrating an operation state of the substrate processing apparatus when a liquid film removing operation of FIG. 4 is performed, and FIG. 21 is an enlarged view of region A of FIG. 20 to illustrate a state of the substrate. FIG. 22 is a diagram illustrating an operation state of the substrate processing apparatus after the liquid film removing operation of FIG. 4 is performed.

FIG. 23 is a diagram schematically illustrating an operation state of the substrate processing apparatus when the edge removing operation according to another exemplary embodiment of the present invention is performed.

FIG. 24 is a top plan view schematically illustrating a substrate processing apparatus according to another exemplary embodiment of the present invention.

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

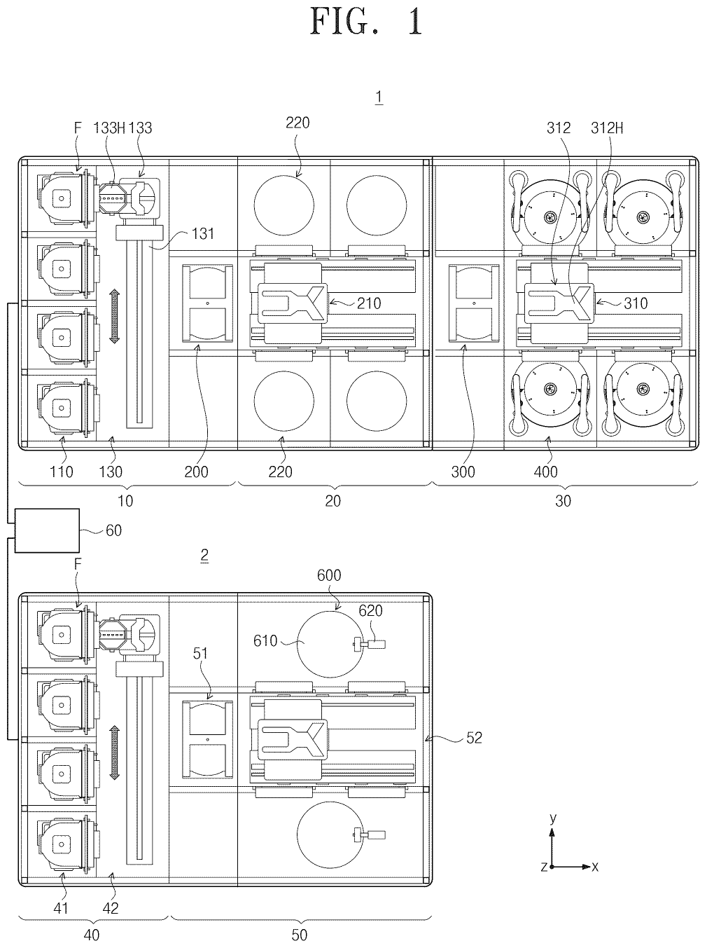

Hereinafter, exemplary embodiment of the present invention will be described with reference to FIGS. 1 to 24.

FIG. 1 is a top plan view schematically illustrating a substrate processing apparatus according to an exemplary embodiment of the present invention. The substrate processing apparatus 1 includes an index unit 10 and a treating module, and the treating module includes a polishing treatment unit 20 and a cleaning treatment unit 30. A second apparatus 2 is provided outside the substrate processing apparatus 1, and the second apparatus 2 includes a second index unit 40 and an edge treatment unit 50. The controller 60 controls the substrate processing apparatus 1 and the second apparatus 2.

According to an exemplary embodiment, the index unit 10, the polishing treatment unit 20, and the cleaning treatment unit 30 are disposed along one direction, and the edge treatment unit 50 is provided as a separate device. Hereinafter, a direction in which the index unit 10, the polishing treatment unit 20, and the cleaning treatment unit 30 are disposed is defined as a first direction X, when viewed from above, a direction perpendicular to the first direction X is defined as a second direction Y, and a direction perpendicular to a plane including both the first direction X and the second direction Y is defined as a third direction Z.

The index unit 10 transfers the substrate W from the container F in which the substrate W is accommodated to the polishing treatment unit 20 for treating the substrate W. The index unit 10 accommodates the substrate W, which has been completely processed in the polishing treatment unit 20 to the cleaning treatment unit 30, into the container F.

Alternatively, the index unit 10 transfers the substrate W from the container F in which the substrate W is accommodated to the second apparatus 2 in which the edge treatment unit 50 for treating the substrate W is provided. The longitudinal direction of the index unit 10 is provided in the second direction Y. The index unit 10 includes a load port 110, an index frame 130, and a first buffer unit 200.

The container F in which the substrate W is accommodated is seated on the load port 110. Based on the index frame 130, the load port 110 is located at a side opposite to the cleaning treatment unit 30. A plurality of load ports 110 may be provided. The plurality of load ports 110 may be arranged in a line along the second direction Y. The number of load ports 110 may increase or decrease according to the process efficiency and footprint conditions of the process treatment units 20 and 30.

A plurality of slots (not illustrated) for accommodating the substrates W in a state of being horizontally arranged with respect to the ground is formed in the carrier F. As the container F, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index rail 131 and an index robot 133 are provided in the index frame 130. The index rail 131 is provided in the index frame 130 along the second direction Y in its longitudinal direction. The index robot 133 may transfer the substrate W. The index robot 133 may transfer the substrate W between the index unit 10 and a first buffer unit 200 to be described later.

The index robot 133 may be provided on the index rail 131 to be movable along the second direction Y. The index robot 133 includes a hand 133H. The substrate W may be placed on the hand 133H. The hand 133H is provided to be able to move forward and backward in the first direction X. Also, the hand 133H may be provided to rotate around the third direction Z and be movable along the third direction Z. A plurality of hands 133H may be provided. A plurality of hands 133H may be provided to be spaced apart from each other in the vertical direction. A plurality of hands 133H may move forward, backward, and rotate independently of each other.

The first buffer unit 200 may be disposed between the index frame 130 and a first transfer chamber 210. The first buffer unit 200 may be located at one end of the first transfer chamber 210. A slot (not illustrated) in which the substrate W is placed is provided in the first buffer unit 200. A plurality of slots (not illustrated) is provided to be spaced apart from each other along the third direction Z. A front face and a rear face of the first buffer unit 200 are opened. The front face is a face facing the index unit 10, and the rear face is a face facing the first transfer chamber 210. The index robot 133 may approach the first buffer unit 200 through the front surface, and a first transfer robot provided to the first transfer chamber 210 to be described later may approach the first buffer unit 200 through the rear surface.

The polishing treatment unit 20 performs a Chemical Mechanical Polishing (CMP) process of flattening the substrate W by rubbing a polishing pad against the substrate W. The polishing treatment unit 20 injects a slurry composition including polishing particles between the substrate W and the polishing pad, and flattens the substrate W by rubbing the polishing pad against the substrate. The polishing treatment unit 20 includes a first transfer chamber 210 and a polishing chamber 220. The polishing chambers 220 may be disposed on opposite sides of the first transfer chamber 210. The first transfer chamber 210 and the polishing chamber 220 may be disposed along the second direction Y. The first transfer chamber 210 may be disposed between the first buffer unit 200 and the cleaning treatment unit 30. The first buffer unit 200 may be positioned at one end of the first transfer chamber 210, and the cleaning treatment unit 30 may be positioned at the other end of the first transfer chamber 210.

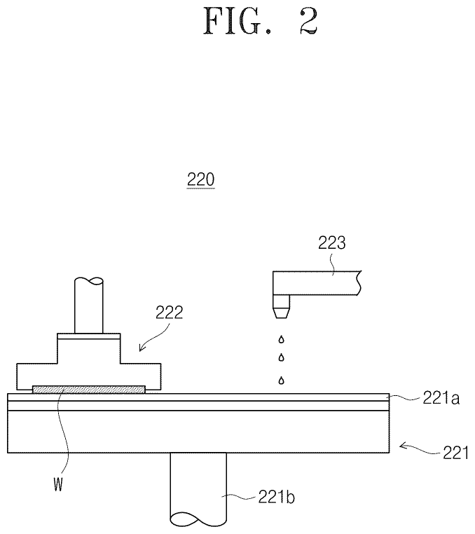

In the polishing chamber 220, a chemical mechanical polishing process is performed on the substrate. FIG. 2 is a diagram schematically illustrating the polishing chamber of FIG. 1. Referring to FIG. 2, the polishing chamber 220 includes a polishing surface plate 221 that rotates while a polishing platen pad 221a is attached to the base, a carrier unit 222 that presses and rotates the substrate W with the platen pad 221a while mounting the substrate W to be polished, and a slurry supply unit 223 that supplies slurry to the upper surface of the platen pad 221a. The slurry flows into the contact surface between the substrate W and the platen pad 221a, and the surface of the substrate W is polished while the substrate W is pressed and rotated at a position spaced apart from the rotation center of the platen pad 221a. Since the chemical mechanical polishing process is a well-known technique, a detailed description will be omitted.

Referring back to FIG. 1, the cleaning treatment unit 30 includes a second buffer unit 300, a second transfer chamber 310, and a plurality of liquid treating chambers 400. The liquid treating chambers 400 may be respectively disposed at opposite sides of the second transfer chamber 310. The liquid treating chamber 400 may be disposed at a side portion of the second transfer chamber 310. The second transfer chamber 310 and the liquid treating chamber 400 may be disposed along the second direction Y. The second transfer chamber 310 may be disposed on the opposite side of the first transfer chamber 210 with respect to the second buffer unit 300. The first transfer chamber 210 may be positioned at one end of the second buffer unit 300, and the second transfer chamber 310 may be positioned at the other end of the second buffer unit 300.

According to an example, the liquid treating chambers 400 may be disposed at opposite sides of the second transfer chamber 310, and the liquid treating chambers 400 may be provided in an arrangement of A×B (A and B are each a natural number equal to or greater than 1) at one side of the second transfer chamber 310 along the first direction X and the third direction Z. Here, A is the number of the liquid treating chambers 400 provided in a line along the first direction X, and B is the number of the liquid treating chambers 400 provided in a line along the third direction Z. For example, when four or six liquid treating chambers 400 are provided at one side of the second transfer chamber 310, the liquid treating chambers 400 may be arranged in a 2×2 or 2×3 arrangement. The number of liquid treating chambers 400 may increase or decrease. Unlike the above description, the liquid treating chamber 400 may be provided only at one side of the second transfer chamber 310. In addition, the liquid treating chamber 400 may be provided as a single layer on one side or opposite sides of the second transfer chamber 310.

The second transfer chamber 310 includes a guide rail and a second transfer robot 312. The guide rail is provided in the second transfer chamber 310 such that its longitudinal direction extends along the first direction X. The second transfer robot 312 may be provided on the guide rail to be able to move linearly in the first direction X. The second transfer robot 312 transfers the substrate W between the second buffer unit 300 and the liquid treating chamber 400 and between the liquid treating chambers 400.

The transfer robot 312 includes a hand 312H on which the substrate W is placed. The hand 312H may be provided on the guide rail to be movable along the first direction X. Accordingly, the hand 312H may be moved forward and backward along the guide rail. Also, the hand 312H may be provided to be rotated around the third direction Z and to be movable along the third direction Z. A plurality of hands 312H may be provided. A plurality of hands 312H may be provided to be spaced apart from each other in the vertical direction. The plurality of hands 312H may move forward, backward, and rotate independently of each other.

The first transfer chamber 210 includes a guide rail and the first transfer robot. The guide rail is provided in the first transfer chamber 210 such that its longitudinal direction extends along the first direction X. The first transfer robot transfers the substrate W between the first buffer unit 200, the polishing chamber 220, and the second buffer unit 300. Since the guide rail of the first transfer chamber 210 and the configuration of the first transfer robot are the same as those of the guide rail of the second transfer chamber 310 and the second transfer robot 312, the detailed description thereof will be omitted.

As illustrated in FIG. 1, the first buffer unit 200, the first transfer chamber 210, the second buffer unit 300, and the second transfer chamber 310 may be sequentially disposed in the first direction X.

The liquid treating chamber 400 may perform a liquid treatment process for liquid-treating the substrate W. For example, the liquid treatment process may be a cleaning process for cleaning the substrate W with a cleaning solution. For example, the liquid treating chamber 400 may be a chamber that performs a cleaning process for removing process by-products or the like attached to the substrate W. Each of the liquid treating chambers 400 may have the same structure. Alternatively, the liquid treating chambers 400 may have different structures depending on the type of process for treating the substrate W.

The second apparatus 2 includes a second index unit 40 and an edge treatment unit 50. Since the second index unit 40 has the same configuration as the index unit 10, a detailed description thereof will be omitted. The second index unit 40 transfers the substrate W from the container F in which the substrate W is accommodated to the edge treatment unit 50 treating the substrate W. The second index unit 40 and the edge treatment unit 50 may be disposed along the first direction X.

An edge trimming process for removing an edge of the substrate W is performed in the edge treatment unit 50. The edge treatment unit 50 includes a third buffer unit 51, a third transfer chamber 52, and an edge trimming chamber 600. The edge trimming chamber 600 may be disposed on opposite sides of the third transfer chamber 52. The third transfer chamber 52 and the edge trimming chamber 600 may be disposed along the second direction Y. The third transfer chamber 52 includes a guide rail and a third transfer robot. The guide rail is provided in the third transfer chamber 52 such that its longitudinal direction extends along the first direction X. The third transfer robot transfers the substrate W between the third buffer unit 51 and the edge treating chamber 600. Since the guide rail of the third transfer chamber 52 and the third transfer robot have the same configuration as the guide rail of the second transfer chamber 310 and the second transfer robot 312, a detailed description thereof will be omitted.

The edge trimming chamber 600 may prevent substrate damage, such as flaking or peeling of the substrate W, during the bonding process by performing the edge trimming process before the bonding process of the substrate W. The edge trimming process is performed by removing the edge portion of the substrate W through a cutting blade 620 while rotating the substrate W by supporting the substrate W on a substrate holding means 610 of an edge trimming device provided in the edge trimming chamber 600 of the edge treatment unit 50. Since the edge trimming device and process are well-known technologies, detailed descriptions thereof will be omitted.

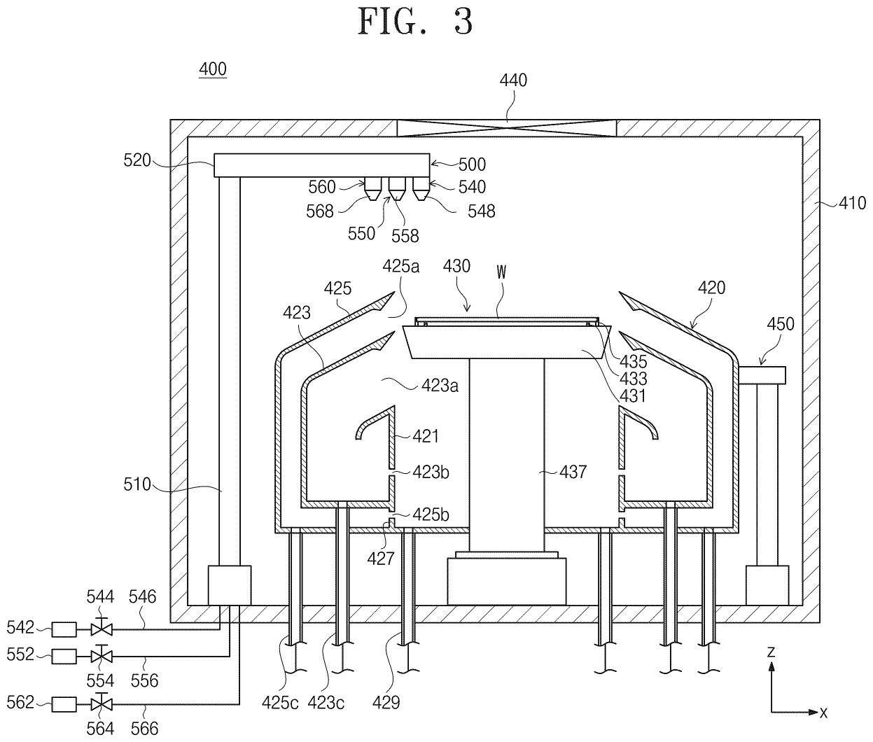

FIG. 3 is a diagram schematically illustrating an exemplary embodiment of the liquid treating chamber of FIG. 1. The liquid treating chamber 400 includes a housing 410, a treatment container 420, a support unit 430, an airflow supply unit 440, a lifting unit 450, and a liquid supply unit 500.

The housing 410 has an inner space. The housing 410 is provided in a generally rectangular parallelepiped shape. An opening (not illustrated) is formed at one side of the housing 410. The opening (not illustrated) functions as an entrance through which the substrate W is loaded into the inner space or the substrate W is unloaded from the inner space. The treatment container 420, the support unit 430, the airflow liquid supply unit 440, and the liquid supply unit 500 are disposed in the housing 410.

The treatment container 420 has a treatment space with an open top. The treatment container 420 may have a bowl shape. The substrate W is located in the treatment space, and the treatment of the substrate W may be performed in the treatment space.

A drainage pipe 421 and an exhaust pipe 423 are coupled to a bottom surface of the treatment container 420. An annular gas-liquid separating plate 425 may be installed on the bottom surface of the treatment container 420. The drainage pipe 421 may be connected to the treatment container 420 in an outer region than the gas-liquid separation plate 425. The exhaust pipe 423 may be connected to the treatment container 420 in an inner region of the gas-liquid separation plate 425. Accordingly, the liquids used for treatment of the substrate W may be discharged to the outside of the treatment container 420 through the drainage pipe 421, and fumes and airflow in the treatment container 420 may be exhausted to the outside of the treatment container 420 through the exhaust pipe 423. A pressure reducing pump may be installed at the exhaust pipe 423.

The support unit 430 supports and rotates the substrate W in the treatment space. The support unit 430 includes a spin chuck 431, a support pin 433, a chuck pin 435, a rotation shaft 437, and a driver 439.

The top surface of the spin chuck 431 is generally provided in a circular shape when viewed from above. The top surface of the spin chuck 431 may be provided to have a larger diameter than the substrate W.

A plurality of support pins 433 is provided. The support pin 433 is disposed on the top surface of the spin chuck 431. The support pin 433 is disposed on the edge of the top surface of the spin chuck 431 to be spaced apart from each other at a predetermined interval. The support pin 433 protrudes upward from the top surface of the spin chuck 431. The support pins 433 are disposed to have an annular ring shape as a whole by a combination thereof. The support pin 433 supports the edge of the back surface of the substrate W so that the substrate W is spaced apart from the top surface of the spin chuck 431 by a predetermined distance.

A plurality of chuck pins 435 is provided. The chuck pin 435 is disposed to be relatively farther from the center of the spin chuck 433 than the support pin 431. The support pin 435 protrudes from the top surface of the spin chuck 431. The chuck pin 335 supports a side portion of the substrate W so as not to be separated from the correct position in the lateral direction when the substrate W is rotated. The chuck pin 435 is provided to be able to move linearly between a standby position and a support position along a radial direction of the spin chuck 431. For example, the chuck pin 435 may be linearly moved in the radial direction of the substrate W between the standby position and the support position. The standby position is a position farther from the center of the spin chuck 431 than the support position. When the substrate W is loaded into or unloaded from the support unit 430, the chuck pin 435 is located at the standby position, and the chuck pin 435 is located at the support position when performing a process on the substrate W. In the support position, the chuck pin 435 is in contact with the side portion of the substrate W.

The rotation shaft 437 is coupled to the spin chuck 431. The rotation shaft 437 may be coupled to a lower surface of the spin chuck 431. The rotation shaft 437 may be provided such that a longitudinal direction thereof faces a vertical direction. The rotation shaft 437 is provided to be rotatable by receiving power from the driver 439. The rotation shaft 437 is rotated by the driver 439, thereby rotating the spin chuck 431. The driver 439 may vary the rotation speed of the rotation shaft 437. The driver 439 may be a motor that provides driving force. However, the present invention is not limited thereto, and may be variously modified and provided as a known device that provides driving force.

The airflow supply unit 440 supplies airflow to the inner space of the housing 410. The airflow supply unit 440 may supply descending airflow to the inner space. The airflow supply unit 440 may be installed on a ceiling of the housing 410. Gas supplied to the inner space of the housing 410 through the airflow supply unit 440 forms a descending airflow in the inner space. Gas by-products generated by the treatment process in the treatment space are discharged to the outside of the housing 410 through the exhaust pipe 423 by the descending airflow. The airflow supply unit 440 may be provided to a Fan Filter Unit (FFU).

The lifting unit 450 is disposed in the housing 410. The lifting unit 450 adjusts the relative height between the treatment container 420 and the support unit 430. The lifting unit 450 may linearly move the treatment container 320 in the third direction 6. Unlike the description, the treatment container 420 is fixedly installed, and the lifting unit 450 may move the support unit 440 in the vertical direction.

The liquid supply unit 500 supplies a liquid to the substrate W. The liquid supply unit 500 supplies the liquid to the substrate W supported by the support unit 430. The liquid supply unit 500 may sequentially supply a plurality of liquids onto the substrate W. The liquid according to the exemplary embodiment of the present invention may be any one of a treatment solution C1, a first removal solution C2, and a second removal solution C3. The liquid supply unit 500 may include a support rod 510, an arm 520, a driver 530, a treatment solution supply unit 540, a first removal solution supply unit 550, and a second removal solution supply unit 560.

The treatment solution supply unit 540 may include a treatment solution supply source 542, a treatment solution supply valve 544, a treatment solution supply line 546, and a treatment solution supply nozzle 548. The first removal solution supply unit 550 may include a first removal solution supply source 552, a first removal solution supply valve 554, a first removal solution supply line 556, and a first removal solution supply nozzle 558. The second removal solution supply unit 560 may include a second removal solution supply source 562, a second removal solution supply valve 564, a second removal solution supply line 566, and a second removal solution supply nozzle 568.

The support rod 510 is located in the inner space of the housing 410. The support rod 510 is located on one side of the treatment container 420 in the inner space. The support rod 510 may have a rod shape whose longitudinal direction faces the third direction Z. The support rod 510 is provided to be rotatable with respect to its central axis by the driver 530 to be described later.

The arm 520 is coupled to an upper end of the support rod 510. The arm 520 extends vertically from the longitudinal direction of the support rod 510. The treatment solution supply nozzle 548, the first removal solution supply nozzle 558, and the second removal solution supply nozzle 568, which will be described later, may be fixedly coupled to the end of the arm 520. The arm 520 may be provided to be able to move forward and backward along the longitudinal direction thereof. The arm 520 may be swing-moved as the driver 530 described later rotates the support rod 510. By rotation of the arm 520, the treatment solution supply nozzle 548, the first removal solution supply nozzle 558, and the second removal solution supply nozzle 568 may also be swing-moved and moved between the process position and the standby position.

When viewed from above, the process position is a position where at least one of the treatment solution supply nozzle 548, the first removal solution supply nozzle 558, and the second removal solution supply nozzle 568 faces the substrate W supported by the support unit 430. The standby position is a position where the treatment solution supply nozzle 548, the removal solution supply nozzle 558, and the second removal solution supply nozzle 568 are all out of the process position when viewed from above.

The driver 530 is coupled with the support rod 510. The driver 530 may be disposed on the bottom surface of the housing 410. The driver 530 provides driving force for rotating the support rod 510. The driver 530 may be provided as a known motor for providing driving force.

The treatment solution supply nozzle 548 supplies the treatment solution C1. The treatment solution supply nozzle 548 supplies the treatment solution C1 onto the substrate W supported by the support unit 430. The treatment solution C1 may include a polymer and a volatile solvent. According to an example, the polymer may include resin. The resin may be an acrylic resin, a phenol resin, an epoxy resin, a polystyrene resin, a polyester resin, an alkyd resin, polyurethane, polyimide, polyethylene, polypropylene, polyvinyl chloride, polyvinyl acetate, polyamide, or another type of resin. The volatile solvent may contain alcohol. The volatile solvent may be a solution that dissolves a polymer and has a volatile component. When the volatile solvent is volatilized in the treatment solution C1 supplied onto the substrate W, the treatment solution C1 is solidified or cured on the substrate W to form a liquid film S.

The treatment solution C1 is supplied from the treatment solution supply source 542 to the treatment solution supply nozzle 548 through the treatment solution supply line 546. The treatment solution supply valve 544 is installed on the treatment solution supply line 546 to open and close the treatment solution supply line 546.

The first removal solution supply nozzle 558 may supply the first removal solution C2 to the substrate W. According to an example, the removal solution supply nozzle 558 may supply the first removal solution C2 onto the substrate W supported by the support unit 430. The first removal solution C2 may remove the liquid film S from the substrate W. According to an example, the first removal solution C2 may be a dissolution solution which dissolves the liquid film S. The first removal solution C2 may be an organic solvent. The first removal solution C2 may include an alcohol which dissolves a resin. The first removal solution C2 may be isopropyl alcohol having a concentration of 90%.

The first removal solution C2 is supplied from the first removal solution supply source 552 to the first removal solution supply nozzle 558 through the first removal solution supply line 556. The first removal solution supply valve 554 is installed on the first removal solution supply line 556 to open and close the first removal solution supply line 556.

The second removal solution supply nozzle 568 may supply the second removal solution C3 to the substrate W. According to an example, the second removal solution supply nozzle 568 may supply the second removal solution C3 onto the substrate W supported by the support unit 430. The second removal solution C3 may strip the liquid film S formed by solidifying the treatment solution C1 on the substrate W from the substrate W. According to an example, the second removal solution C3 may be deionized water (DIW). According to an example, the second removal solution C3 may be mixed with the first removal solution C2 in a manner in which the second removal solution C3 is supplied together with the first removal solution C2 and may be supplied to the substrate W.

The second removal solution C3 is supplied from the second removal solution supply source 562 to the second removal solution supply nozzle 568 through the second removal solution supply line 566. The second removal solution supply valve 564 is installed on the second removal solution supply line 566 to open and close the second removal solution supply line 566.

Although the present invention has been described based on the case where in the liquid supply unit 500 according to the exemplary embodiment of the present invention, the treatment solution supply nozzle 548, the first removal solution supply nozzle 558, and the second removal solution supply nozzle 568 are all coupled to the arm 520 as an example, the present invention is not limited thereto. For example, the treatment solution supply nozzle 548, the first removal solution supply nozzle 558, and the second removal solution supply nozzle 568 may each independently have an arm, a support rod, and a driver, and may independently swing and move forward and backward.

Although the present invention has been described based on the case where in the liquid supply unit 500 according to the exemplary embodiment of the present invention, the treatment solution supply nozzle 548, the first removal solution supply nozzle 558, and the second removal solution supply nozzle 568 are provided to the arm 520 as an example, the present invention is not limited thereto. The liquid supply unit 500 may further include a nozzle which is not illustrated and an additional configuration accordingly.

The controller 60 may control the substrate processing apparatus. The controller 60 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a processing recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 60 may control the substrate processing apparatus 1 and the second apparatus 2 to perform the substrate processing method described below.

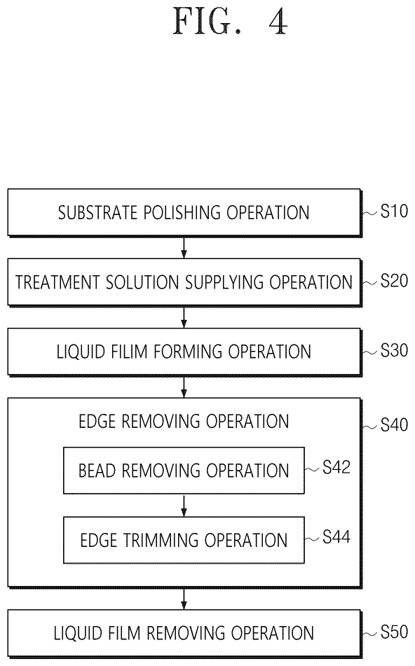

Hereinafter, an exemplary embodiment of a method of processing the substrate W using the substrate processing apparatus 1, the second apparatus 2, and the liquid treating chamber 400 of FIG. 3 will be described. FIG. 4 is a flowchart of the substrate processing method of the present invention. Referring to FIG. 4, the substrate processing method includes a substrate polishing operation S10, a treatment solution supplying operation S20, a liquid film forming operation S30, an edge removing operation S40, and a liquid film removing operation S50, and the edge removing operation S40 includes a bead removing operation S42 and an edge trimming operation S44.

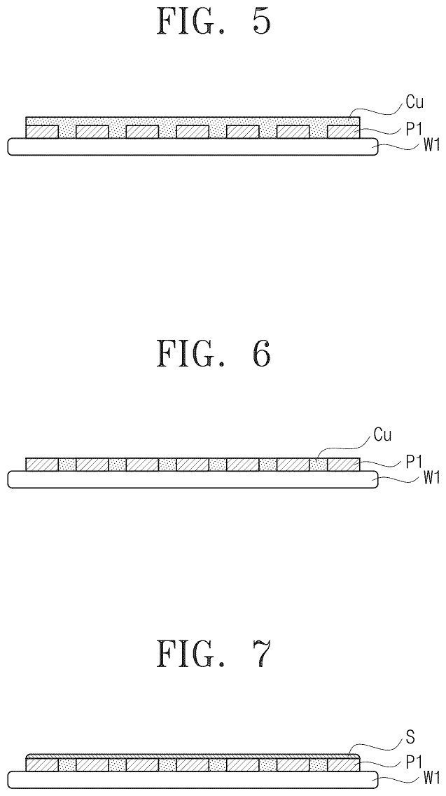

FIGS. 5 to 10 are diagrams schematically illustrating a process of treating a substrate using the substrate processing method of FIG. 4.

Referring to FIG. 5, a pattern P1 is formed on a top surface of a first substrate W1, and a metal layer is formed on the pattern P1. For example, the metal layer may be formed by plating, Physical Vapor Deposition (PVD), or the like. The metal layer may include copper (Cu). The metal layer may be formed using a metal other than copper (Cu), but hereinafter, a case in which the metal layer is a copper (Cu) layer will be described as an example.

FIG. 6 schematically illustrates a state of the first substrate on which the metal layer formed on an upper portion of the pattern is polished through a polishing process. Foreign substances, such as particles, generated during the polishing process of a copper (Cu) layer remain on the first substrate W1, and a cleaning process of cleaning the substrate is performed to remove the foreign substances. In addition, in order to prevent the edge portion of the substrate from being damaged when the first substrate W1 is bonded to another substrate, an edge removal process of trimming the edge portions of the substrates used for bonding, including the first substrate W1, needs to be performed.

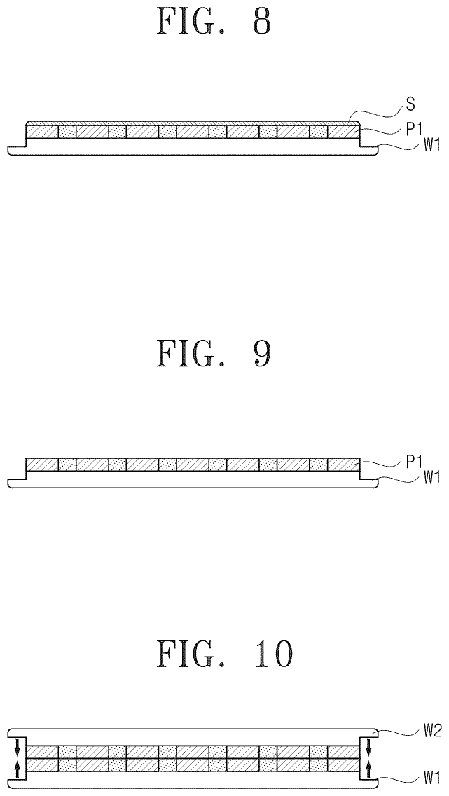

In the substrate processing method according to the exemplary embodiment of the present invention, first, a liquid film S is formed as illustrated in FIG. 7 by supplying a treatment solution to the first substrate W1, and then, as illustrated in FIG. 8, an edge removal process of trimming a part of the edge end of the first substrate W1 is performed, and then, as illustrated in FIG. 9, the liquid film formed on the first substrate W1 is removed by supplying a removal solution to the first substrate W1.

A bonding process of bonding the first substrate W1 from which the liquid film has been removed through the above process and the second substrate W2 from which the liquid film has been removed by performing the same process is performed (see FIG. 10). That is, the substrate processing method of the present invention may further include a substrate bonding process of bonding the pattern surface of the second substrate W2 on which the substrate polishing operation S10 or the liquid film removing operation S50 has been performed to the pattern surface of the first substrate W1 on which the substrate polishing operation S10 or the liquid film removing operation S50 has been performed.

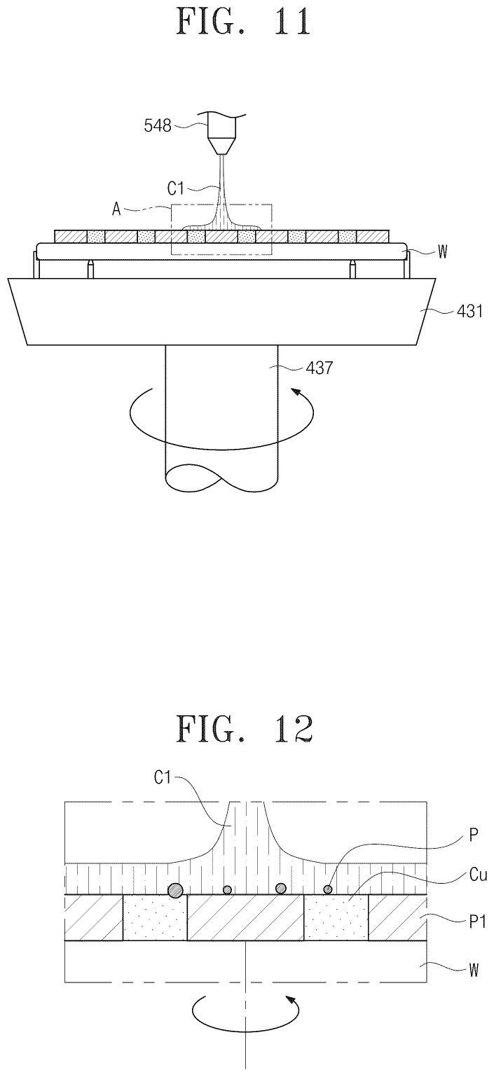

Hereinafter, the process of cleaning and removing the edge of the substrate, which has been schematically described with reference to FIGS. 7 to 9, that is, the treatment solution supplying operation S20, the liquid film forming operation S30, the edge removing operation S40, and the liquid film removing operation S50 of FIG. 4 will be described in detail with reference to FIGS. 11 to 23. For convenience of description, in the following drawings, the state of the substrate W will be illustrated such that the copper (Cu) layer illustrated in FIGS. 5 to 10 is schematically illustrated as filling the spaces between the patterns P1 formed on the substrate W.

FIG. 11 is a diagram schematically illustrating an operation state of the substrate processing apparatus when the treatment solution supplying operation of FIG. 4 is performed, and FIG. 12 is an enlarged view of region A of FIG. 11 to illustrate a state of the substrate. When the substrate W is placed on the spin chuck 431, the treatment solution supplying operation S10 is performed. In the treatment solution supplying operation S10, the treatment solution C1 is supplied onto the rotating substrate W.

Referring to FIG. 11, the treatment solution supply nozzle 548 is placed at the process position. In the treatment solution supplying operation S10, the treatment solution supply line 546 is opened and the removal solution supply valve 554 is closed. When the substrate W rotates, the treatment solution C1 is supplied from the treatment solution supply nozzle 548 toward the center of the substrate W.

The treatment solution C1 supplied to the substrate W spreads from the central region of the substrate W to the edge region by the rotation of the substrate W and is applied to the entire substrate W.

Referring to FIG. 12, foreign substances, such as particles P, and the like generated during the polishing process of the copper (Cu) layer remain on the substrate W. As illustrated in FIG. 12, some particles P may be embedded in a copper layer. The treatment solution C1 supplied to the substrate W covers the entire upper surface of the pattern formed on the substrate W.

When the treatment solution supplying operation S10 is completed, a liquid film forming operation S20 is performed. In the liquid film forming operation S20, the substrate W rotates without supplying liquid.

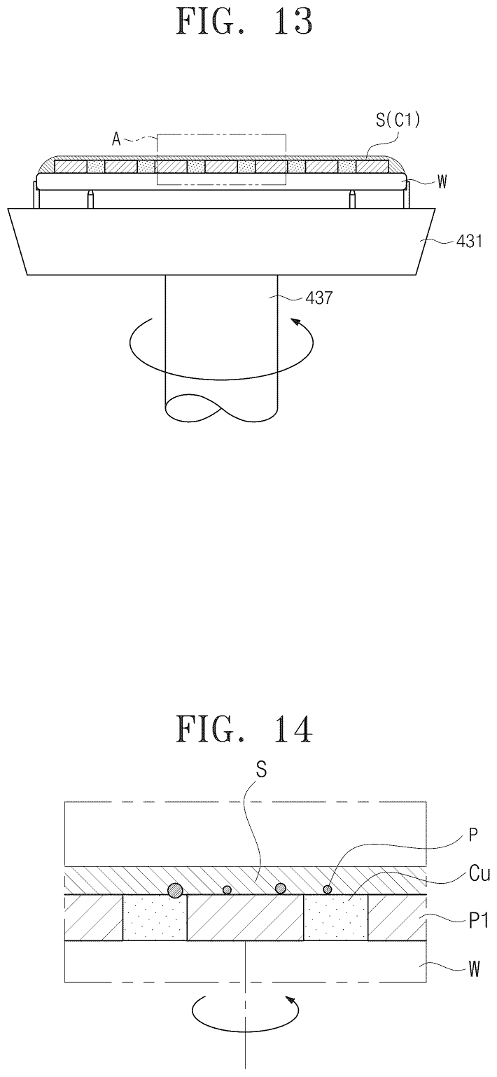

FIG. 13 is a diagram schematically illustrating an operation state of the substrate processing apparatus when the liquid film forming operation of FIG. 4 is performed, and FIG. 14 is an enlarged view of region A of FIG. 13 to illustrate a state of the substrate.

Referring to FIG. 13, a volatile solvent in the treatment solution C1 is volatilized by the rotation of the substrate W, and the treatment solution C1 is solidified or cured. As a result, the liquid film S of the treatment solution C1 is formed on the upper surface of the substrate W.

Referring to FIG. 14, as the volatile solvent volatilizes, volume contraction of the treatment solution C1 occurs. As the volatile solvent continuously volatilizes, the treatment solution C1 is solidified or cured, and in this process, the particles P remaining on the substrate W are dropped from the substrate W due to the tension caused by volume contraction and are trapped in the liquid film S of the treatment solution C1.

After the liquid film forming operation S20, the edge removing operation S40 is performed on the substrate W on which the liquid film S is formed. The edge removing operation S40 is an operation of removing the liquid film S formed at the edge portion of the substrate W and the edge portion of the substrate W. The edge removing operation S40 includes a bead removing operation S42 and an edge trimming operation S44.

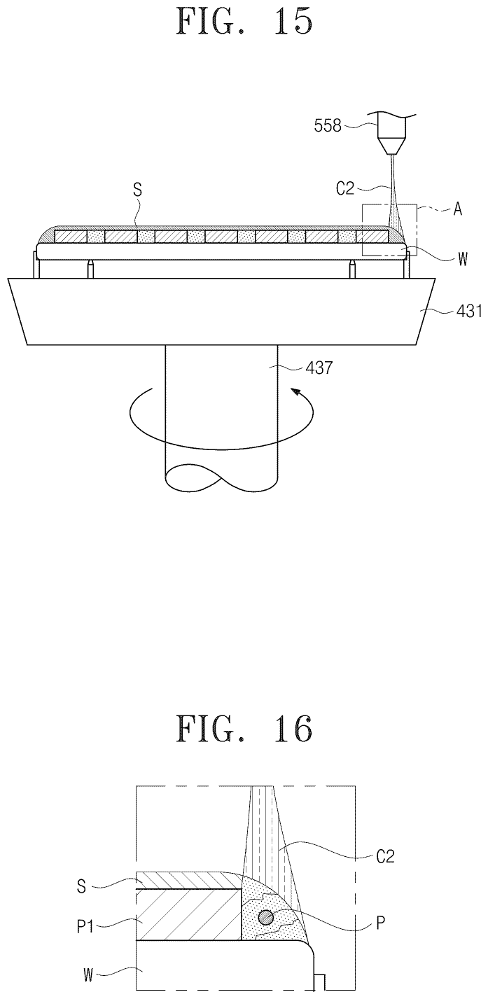

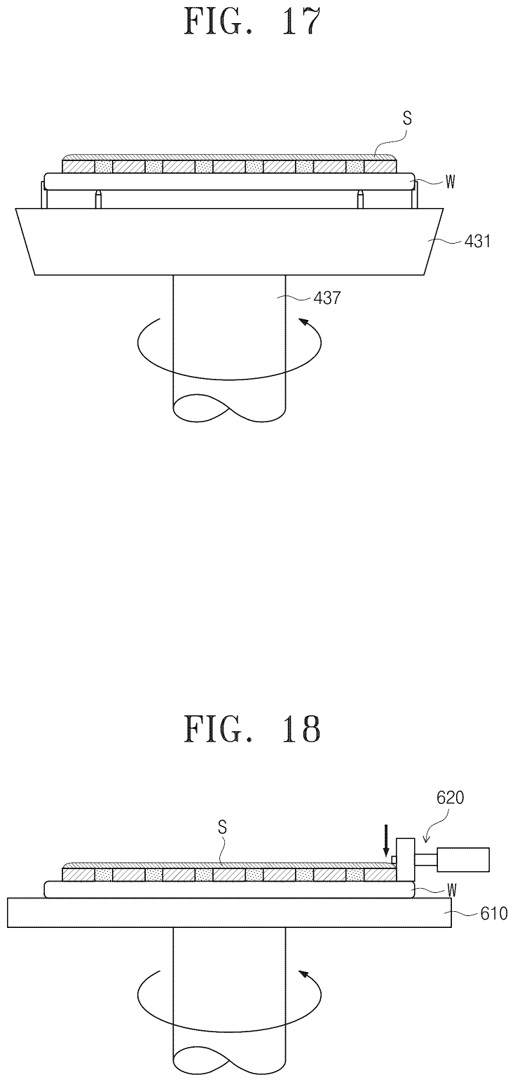

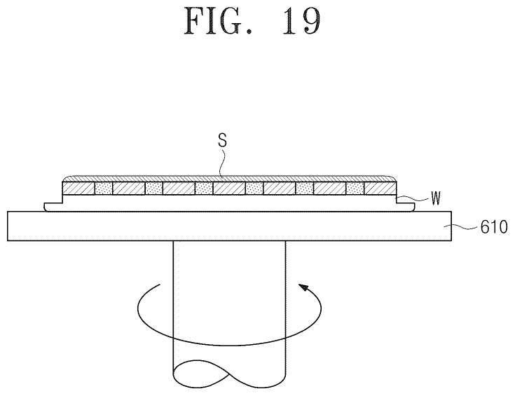

FIG. 15 is a diagram schematically illustrating an operation state of the substrate processing apparatus when the bead removing operation of FIG. 4 is performed, and FIG. 16 is an enlarged view of region A of FIG. 15 to illustrate a state of the substrate. FIG. 17 is a diagram illustrating an operation state of the substrate processing apparatus after the bead removing operation of FIG. 4 is performed.

Referring to FIG. 15, in the bead removing operation S42, a dissolution solution is supplied to the upper portion of the edge portion of the substrate W to remove the liquid film S formed on the edge portion of the substrate W. The first removal solution supply nozzle 558 is placed above the edge region of the substrate W by rotation of the arm 520. Thereafter, the substrate W rotates, and the first removal solution supply valve 554 is opened, and thus the first removal solution C2, which is a dissolution solution for dissolving the liquid film S, is supplied from the first removal solution supply source 552. The first removal solution supply nozzle 558 supplies the first removal solution C2 to the edge portion of the substrate W. By rotation of the substrate W, the first removal solution C2 spreads outward from the upper portion of the edge portion of the substrate W and is applied to the upper portion of the edge portion of the substrate W. The edge portion of the substrate W may mean a region of the substrate W to be removed in the edge trimming operation S44 to be described later.

Referring to FIG. 16, the first removal solution C2 dissolves the liquid film S, and the dissolved liquid film S is removed from the substrate W according to the rotation of the substrate W. When the dissolved liquid film S is removed from the substrate W according to the rotation of the substrate W, the particles P trapped in the liquid film at the edge portion of the substrate W may also be removed. As described above, in the edge removing operation S40, the liquid film S present in an upper portion of the region in which the edge trimming is performed may be removed before the edge trimming operation S44 is performed (FIG. 17).

When the bead removing operation S42 is terminated, the edge trimming operation S44 is performed. The edge trimming operation S44 may be performed in the edge trimming chamber 600 described above without being performed in the liquid treating chamber 400. The substrate W may be transferred from the liquid treating chamber 400 to the second apparatus 2 located outside the substrate processing apparatus 1 through the second transfer chamber 310, the second buffer unit 300, the first transfer chamber 210, the index robot 133, and the load port 110, and may be transferred to the edge trimming chamber 600 through the third transfer chamber 52 via the second index unit 40 of the second apparatus.

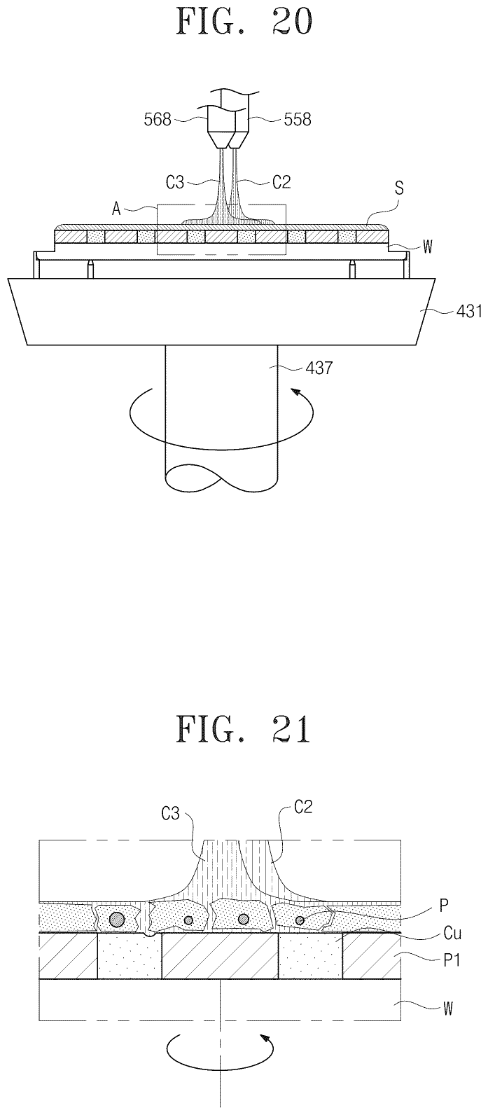

FIG. 18 is a diagram schematically illustrating a state of the substrate when the edge trimming operation of FIG. 4 is performed, and FIG. 19 is a diagram schematically illustrating a state of the substrate after the edge trimming operation of FIG. 4 is performed.

Referring to FIG. 18, an edge trimming process of removing (trimming) the edge portion of the substrate W supported and rotated by the substrate holding means 610 through the cutting blade 620 is performed. The substrate W after the edge trimming operation S44 is performed is in a state in which the edge portion is partially removed, as illustrated in FIG. 19.

Contaminants, such as fragments of the substrate W or particles, generated when trimming the edge portion of the substrate W in the edge trimming operation S44 are captured by the liquid film S formed on the substrate W even if they are scattered toward the substrate W. In other words, the liquid film S formed on the substrate W in the liquid film forming operation S30 may prevent contaminants generated in the edge trimming operation S44 from contaminating the substrate W and prevent scratches from occurring during treatment of the substrate W.

When the edge trimming operation S44 is terminated, the substrate W is loaded into the liquid treating chamber 400, and the liquid film removing operation S50 is performed.

FIG. 20 is a diagram schematically illustrating an operation state of the substrate processing apparatus when the liquid film removing operation of FIG. 4 is performed, and FIG. 21 is an enlarged view of region A of FIG. 20 to illustrate a state of the substrate. FIG. 22 is a diagram illustrating an operation state of the substrate processing apparatus after the liquid film removing operation of FIG. 4 is performed.

The first removal solution supply nozzle 558 and the second removal solution supply nozzle 568 supply the first removal solution C2 and the second removal solution C3 to the central region of the substrate W. The first removal solution C2 and the second removal solution C3 spread from the central region of the substrate W to the edge region by rotation of the substrate W in a mixed state and are applied to the entire substrate W.

Referring to FIG. 21, the mixed solution of the first removal solution C2 and the second removal solution C3 strips the liquid film S from the wafer and simultaneously dissolves the liquid film S. The liquid film S may be stripped off from the substrate W on which the pattern is formed by the second removal solution C3. The second removal solution C3 may penetrate into the liquid film S of the solidified treatment solution C1. As the second removal solution C3 penetrates into the interface between the liquid film S of the treatment solution C1 and the substrate W, the liquid film S of the treatment solution C1 may be stripped from the substrate W. Thus, the particles P attached to the pattern formed surface of the substrate W may be stripped from the substrate W together with the liquid film S. In this process, the particles P embedded in the copper (Cu) layer may be stripped from the substrate W as illustrated in FIG. 21. The concaved copper (Cu) layer may be restored later during the bonding and annealing processes of the substrate W.

The liquid film S stripped by the second removal solution C3 may be dissolved by the first removal solution C2 and washed out of the substrate W by rotation of the substrate W. Also, the first removal solution C2 may replace the second removal solution C3 present on the substrate W.

After the liquid film removing operation S40, the first removal solution C2 and the second removal solution C3 remaining on the substrate W are dried (see FIG. 22). The substrate W is rotated at a high speed while the liquid supply to the substrate W is stopped, and the first removal solution C2 and the second removal solution C3 remaining on the substrate W are volatilized by centrifugal force.

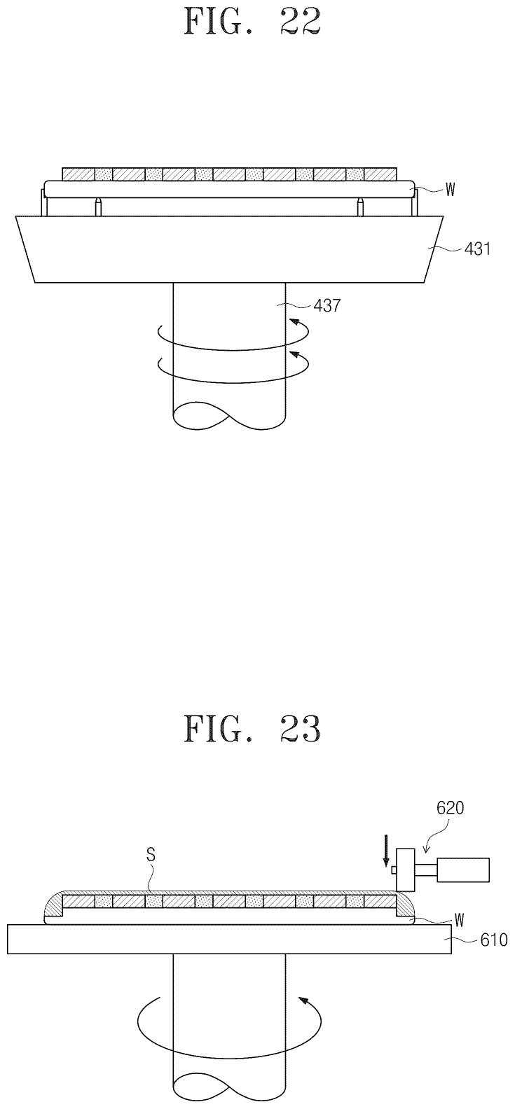

FIG. 23 is a diagram schematically illustrating an operation state of the substrate processing apparatus when the edge removing operation according to another exemplary embodiment of the present invention is performed. Referring to FIG. 23, the edge removing operation S40 according to another exemplary embodiment of the present invention differs from the exemplary embodiments of FIGS. 15 to 19 in that both the bead removing operation S42 and the edge trimming operation S44 are performed in the edge trimming chamber 600. The liquid film S formed in the edge portion of the substrate W is not removed through the first removal solution C2, but the liquid film S supported and rotated by the substrate maintaining means 610 and the edge portion may be removed (trimmed) together through the cutting blade 620.

When the liquid film S is removed through the cutting blade 620, a polymer component included in the liquid film S may adhere to the cutting blade 620 to contaminate the cutting blade 620. Accordingly, after removing the liquid film S and the edge portion of the substrate W through the cutting blade 620, a blade cleaning operation of cleaning the cutting blade 620 to remove the polymer component adhered to the cutting blade 620 may be further included.

As described above, in the substrate processing method according to the exemplary embodiment of the present invention, particles remaining on the substrate W after polishing the substrate may be captured by forming the liquid film S, while contaminants, such as fragments of the substrate W or particles, generated when performing the treatment process of the substrate W, that is, the edge trimming operation S44, may be prevented from contaminating the substrate W or scratches may be prevented from occurring on the substrate W.

As described above, as in the prior art, after cleaning the particles remaining on the substrate W after polishing the substrate, edge trimming is performed, the substrate is cleaned again, and then the substrate is bonded, there was a problem that several times of cleaning processes took time. According to the exemplary embodiment of the present invention, the substrate processing method can omit several cleaning processes by forming a liquid film on the substrate where particles remain by performing a polishing process, performing an edge trimming process, and then removing the liquid film, so that the substrate may be efficiently cleaned, the bonding process of the substrate may be efficiently performed, and the substrate may be efficiently processed.

In the above-described example, it has been described that the substrate W is dried by rotating the substrate W at high speed in the liquid treating chamber after the liquid film removing operation S40. However, unlike this, the substrate W may be dried by supplying a supercritical fluid from a separately provided chamber, or after drying the substrate W by rotating the substrate W at high speed in the liquid treating chamber, a separately provided chamber may supply a supercritical fluid and dry the substrate W.

In the above-described example, it has been described that the first removal solution C2 and the second removal solution C3 are simultaneously supplied onto the substrate W in the liquid film removing operation S50. However, unlike this, after the second removal solution C3 is first supplied onto the substrate W to strip the liquid film S, the first removal solution C2 may be sequentially supplied to wash the stripped liquid film S. In this case, the second removal solution C3 may function as a stripping solution for stripping the liquid film S, and the first removal solution C2 may function as a rinse liquid for cleaning the substrate W. Alternatively, only the first removal solution C2 may be supplied onto the substrate W to dissolve the liquid film S and remove the liquid film S from the substrate W.

In the above example, it has been illustrated and described that the first removal solution C2 and the second removal solution C3 are supplied from different supply nozzles. However, unlike this, the first removal solution C2 and the second removal solution C3 may be discharged from a single supply nozzle to the substrate W in a mixed state.

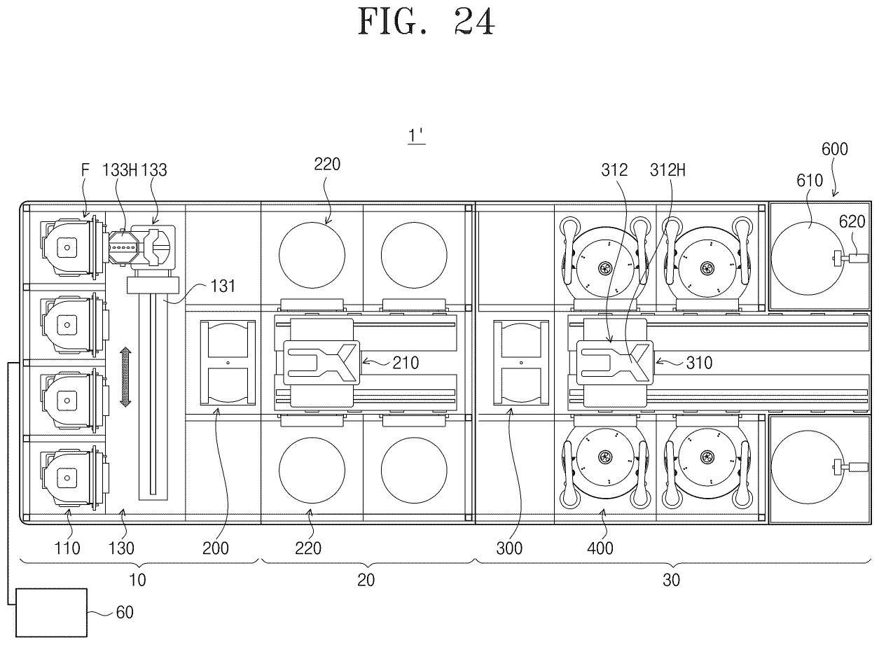

FIG. 24 is a top plan view schematically illustrating a substrate processing apparatus according to another exemplary embodiment of the present invention. In the exemplary embodiments of FIGS. 1 to 23 described above, it has been illustrated and described that the second apparatus 2 including the edge treating chamber 600 is provided outside the substrate processing apparatus 1.

However, unlike this, the substrate processing apparatus 1′ illustrated in FIG. 24 may include a polishing chamber 220, a liquid treating chamber 400, and an edge trimming chamber 600. The edge trimming chamber 600 may be disposed on opposite sides of the second transfer chamber 310. According to the exemplary embodiment, an index unit 10, a polishing treatment unit 20, and a cleaning treatment unit 30 may be disposed along one direction, and a second buffer unit 300, a liquid treating chamber 400, and an edge trimming chamber 600 of the cleaning treatment unit 30 may be disposed along the first direction X. A second transfer robot 312 of a second transfer chamber 310 may transfer the substrate W between the second buffer unit 300, the liquid treating chamber 400, and the edge trimming chamber 600.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate processing method comprising:
a substrate polishing operation of polishing a substrate;
after the polishing operation, a treatment solution supplying operation of supplying a treatment solution containing a polymer and a volatile solvent onto the rotating substrate;
after the treatment solution supplying operation, a liquid film forming operation of volatilizing the volatile solvent in the treatment solution to form a liquid film; and
after the liquid film forming operation, an edge removing operation of removing the liquid film formed on an edge portion of the substrate and the edge portion of the substrate.

2. The method of claim 1, wherein the edge removing operation includes:
a bead removing operation of removing the liquid film formed on an edge region of the substrate; and
an edge trimming operation of removing the edge region of the substrate.

3. The method of claim 2, wherein the bead removing operation and the edge trimming operation are performed by mechanical cutting.

4. The method of claim 2, wherein in the bead removing operation, a dissolution solution is supplied to the substrate to remove the liquid film formed on the edge portion, and
in the edge trimming operation, the edge portion of the substrate is removed by mechanical cutting.

5. The method of claim 1, wherein in the liquid film forming operation, the supply of the treatment solution is stopped.

6. The method of claim 1, further comprising:
after the edge removing operation, a liquid film removing operation of removing the liquid film from an entire region of the substrate.

7. The method of claim 6, wherein in the liquid film removing operation, a removal solution is supplied to the substrate to strip the liquid film from the substrate and at the same time dissolve and remove the liquid film.

8. The method of claim 7, wherein the removal solution contains isopropyl alcohol (IPA).

9. The method of claim 6, wherein in the liquid film removing operation, a stripping solution is supplied to the substrate to strip the liquid film from the substrate.

10. The method of claim 6, wherein in the liquid film removing operation, a dissolution solution is supplied to the substrate to dissolve and remove the liquid film.

11. The method of claim 3, wherein the mechanical cutting is performed by a cutting blade, and
the method further comprises, after the edge removing operation, a blade cleaning operation of cleaning the cutting blade.

12. The method of claim 1, wherein the polymer contains a resin.

13. The method of claim 6, further comprising:
a substrate bonding process of bonding a pattern surface of a second substrate where the liquid film removing operation has been performed to a pattern surface of a first substrate where the liquid film removing operation has been performed.

14. The method of claim 1, wherein in the substrate polishing operation, a copper (Cu) film remaining on the substrate is polished.

15. A substrate processing method comprising:
a substrate polishing operation of polishing a substrate;
after the polishing operation, a treatment solution supplying operation of supplying a treatment solution containing a polymer and a volatile solvent onto the rotating substrate;
after the treatment solution supplying operation, a liquid film forming operation of volatilizing the volatile solvent in the treatment solution to form a liquid film;
after the liquid film forming operation, an edge removing operation of removing the liquid film formed on an edge portion of the substrate and the edge portion of the substrate; and
after the edge removing operation, a liquid film removing operation of supplying a removal solution to the substrate to strip the liquid film from the substrate and at the same time dissolve and remove the liquid film.

16. The method of claim 15, wherein the polymer contains a resin, and
the removal solution contains isopropyl alcohol (IPA).

17. The method of claim 15, wherein the edge removing operation includes:
a bead removing operation of removing the liquid film formed on the edge portion of the substrate; and
an edge trimming operation of removing the edge portion of the substrate.

18. The method of claim 17, wherein in the bead removing operation, a dissolution solution is supplied to the substrate to remove the liquid film formed on the edge portion, and
in the edge trimming operation, the edge portion of the substrate is removed by mechanical cutting.

19. The method of claim 18, wherein the dissolution solution is isopropyl alcohol (IPA).

20. A substrate processing method comprising:
a substrate polishing operation of polishing a substrate with a polishing pad;
after the polishing operation, a treatment solution supplying operation of supplying a treatment solution containing a polymer and a volatile solvent onto the rotating substrate;
after the treatment solution supplying operation, a liquid film forming operation of forming a liquid film of the treatment solution by stopping the supply of the treatment solution, and volatilizing the volatile solvent in the treatment solution and solidifying or curing the treatment solution;
after the liquid film forming operation, an edge removing operation of removing the liquid film formed on an edge portion of the substrate and the edge portion of the substrate; and
after the edge removing operation, a liquid film removing operation of supplying a removal solution to the substrate to strip the liquid film from the substrate and at the same time dissolve and remove the liquid film,
wherein the edge removing operation includes:
a bead removing operation of removing the liquid film formed on an edge region of the substrate; and
an edge trimming operation of removing the edge region of the substrate,
in the bead removing operation, a dissolution solution is supplied to the substrate to remove the liquid film formed on the edge region, and
in the edge trimming operation, the edge region of the substrate is removed by mechanical cutting.
